(19) United States
(12) Patent Application Publication
(10) Pub. No.: US 2025/0190672 A1
(43) Pub. Date: Jun. 12, 2025

(54) DESIGN METHOD AND DESIGN SYSTEM FOR PLACING AND ROUTING SEMICONDUCTOR DEVICES

(71) Applicants: Jae Heon JUNG, Seoul (KR); Yu Mi LEE, Incheon (KR); SLZ Inc., Siheung-si (KR)

(72) Inventors: Jae Heon JUNG, Seoul (KR); Yu Mi LEE, Incheon (KR)

(73) Assignees: Jae Heon JUNG, Seoul (KR); Yu Mi LEE, Incheon (KR); SLZ Inc., Siheung-si (KR)

(21) Appl. No.: 18/436,507

(22) Filed: Feb. 8, 2024

(30) Foreign Application Priority Data
Dec. 12, 2023 (KR) 10-2023-0179665

(51) Int. Cl. G06F 30/3947; G06F 30/392; G06F 30/398

(52) U.S. Cl. CPC G06F 30/3947; G06F 30/392; G06F 30/398

(57) ABSTRACT

A design method for placing and routing a semiconductor device in a computer system includes placing, by the computer system, a plurality of semiconductor devices in a design region, calculating and evaluating, by the computer system, a routing path between the plurality of semiconductor devices, based on a first algorithm, calculating, by the computer system, the routing path between the plurality of semiconductor devices based on a result calculated through the first algorithm and a second algorithm, based on an evaluation result, and comparing the result calculated through the first algorithm with a result calculated through the second algorithm, and verifying the result calculated through the first algorithm, based on a comparison result.

### CROSS-REFERENCE TO RELATED APPLICATIONS

A claim for priority under 35 U.S.C. § 119 is made to Korean Patent Application No. 10-2023-0179665 filed on Dec. 12, 2023 in the Korean Intellectual Property Office, the entire contents of which are hereby incorporated by reference.

### BACKGROUND

Embodiments of the present disclosure relate to a design method and a design system for placing and routing a semiconductor device, and more particularly, relate to a design method and a design system for optimally designing the placement of a semiconductor device and the routing path of the semiconductor device based on a design rule.

Semiconductor integrated circuits may be fabricated by patterning devices and interconnections between devices on a substrate such as a semiconductor wafer. To this end, an Electronic Design Automation (EDA) scheme may be used, and the placement and the routing path of various components and routing may be designed through the EDA scheme.

However, as the degree of integration of semiconductor integrated circuits is increased, the EDA scheme through an existing algorithm has a problem, so researches and studies on various schemes for optimizing semiconductor design are being performed.

### PRIOR ARTS

### Patent Document

U.S. Pat. No. 8,490,042 (Jul. 16, 2013))

### SUMMARY

Embodiments of the present disclosure provide to a design method and a design system for optimally designing the placement of a semiconductor device and the routing path of the semiconductor device based on a design rule.

Embodiments of the present disclosure provide to a design method and a design system for designing the placement of a semiconductor device and the routing path of the semiconductor device, capable of placing a micro-cell and a standard cell to reduce a deadspace and of designing the routing path to minimize a wire length, by utilizing plurality of algorithms.

Problems to be solved by the present disclosure are not limited to the problems mentioned above, and other problems not mentioned will be clearly understood by those skilled in the art from the following description.

According to an embodiment, a design method for placing and routing a semiconductor device in a computer system includes placing, by the computer system, a plurality of semiconductor devices in a design region, calculating and evaluating, by the computer system, a routing path between the plurality of semiconductor devices, based on a first algorithm, calculating, by the computer system, the routing path between the plurality of semiconductor devices based on a result calculated through the first algorithm and a second algorithm, based on an evaluation result, and comparing the result calculated through the first algorithm with a result calculated through the second algorithm, and verifying the result calculated through the first algorithm, based on a comparison result.

The placing of by the computer system, the plurality of semiconductor devices in the design region includes placing, by the computer system, semiconductor devices, which have a higher connection frequency, from among the plurality of semiconductor devices to be closer to each other, and randomly placing remaining semiconductor devices from among the plurality of semiconductor devices.

In the placing of by the computer system, the plurality of semiconductor devices in the design region, the plurality of semiconductor devices include a plurality of macros and a plurality of standard cells, and the computer system places the plurality of standard cells, after placing the plurality of macros, along an edge of the design region

The first algorithm is to recognize a shape of an avoidance target in calculating the routing path, and delete a path graph, which is overlapped with the avoidance target, among path graphs for all possible routing paths from a start node to an end node, after generating the path graph for the all possible routing paths from the start node to the end node, and the second algorithm is to recognize a shape of an avoidance target as a shape of a cylinder-type box in calculating the routing path, move a position of a node, such that regions, which are overlapped with each other, of boxes are pushed, when regions, which are overlapped with each other, of boxes are present, and maintain the boxes, such that the regions, which are overlapped with each other, of the boxes are absent, when the regions are disappeared, as the position of the node moves, and calculate the routing path in a manner of adjusting the position of the node such that a path between adjacent nodes forms a right angle.

The first algorithm is to generate the routing path in a horizontal direction, a vertical direction through a via, and a diagonal direction, when the design region includes a plurality of layers.

The computer system calculates and compare the routing path based on the second algorithm, when a present evaluation score is higher than a previous evaluation score, depending on the evaluation result, and places the plurality of semiconductor devices, calculates the routing path based on the first algorithm, and evaluates the routing path based on the first algorithm, when the present evaluation score is not higher than the previous evaluation score, depending on the evaluation result, depending on the evaluation result.

An evaluation score is determined depending on a wire length resulting from the routing path and the number of elbows.

The computer system calculates the routing path between the plurality of semiconductor devices, based on the result calculated through the first algorithm and the second algorithm, and calculates the routing path between the plurality of semiconductor devices, based on the number of elbows obtained from the result calculated through the first algorithm and the second algorithm.

The comparing of by the computer system, the result calculated through the first algorithm with the result calculated through the second algorithm includes determining whether a movement amount when a node based on the result calculated through the first algorithm is moved to a node based on the result calculated through the second algorithm is less than a preset movement amount.

The computer system verifies the calculation result based on the first algorithm, when the movement amount of the nodes is less than the preset movement amount, depending on the comparison result, and calculates the routing path between the plurality of semiconductor devices, based on the result calculated through the first algorithm and the second algorithm, when the movement amount of the nodes is not less than the preset movement amount, depending on the comparison result.

The verifying of by the computer system, the result calculated through the first algorithm includes determining whether a node reaches an end node based on the result calculated through the second algorithm even if the result calculated through the first algorithm is satisfied.

A computer-readable recording medium having program to execute a design method for placing and routing a semiconductor device, in a computer system, in link to a computer implemented in hardware may be provided.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a block diagram illustrating a semiconductor design system, according to an embodiment of the present disclosure;

FIG. 2 is a view illustrating modifying a moving path to avoid an avoidance target by generating an additional node through a second algorithm;

FIGS. 3A, 3B, and 3C and FIGS. 4A and 4B are views illustrating the features of a second algorithm;

FIGS. 5 and 6 are views illustrating modifying a routing path to avoid an avoidance target by generating a node through a first algorithm;

FIG. 7 is a view illustrating features of a first algorithm;

FIG. 8 is a flowchart illustrating a design method, according to an embodiment of the present disclosure;

FIG. 9 is a view illustrating the placement of a plurality of semiconductor devices;

FIG. 10 is a view illustrating the shortest distance of a routing path through a via; and

FIG. 11 is a view illustrating the generation of a bypass path according to a second algorithm;

### DETAILED DESCRIPTION

The same reference numerals will be assigned to the same components throughout the whole specification. In the following description of the present specification, all components are not described, and content well known in the art to which the present disclosure pertains or the duplication between embodiments will be omitted. In the specification, the terms “unit”, “˜module”, “˜member” or “˜block” may be implemented in software or hardware. According to embodiments, a plurality of units, a plurality of modules, a plurality of members, or a plurality of blocks can be implemented by using one component or one unit, one module, one member, or one block may include a plurality of components.

In the whole specification, when a certain part is “linked to”, “coupled to”, or “connected with” another part, the certain part may be directly linked to, coupled to or connected with the another part, and an indirection link, an indirection coupling, or an indirection connection includes a link, a coupling, or a connection through a wireless communication network.

It will be understood that the terms “comprises,” “comprising,” “includes” and/or “including,” when used herein, specify the presence of stated elements and/or components, but do not preclude the presence or addition of one or more other elements and/or components.

In the present specification, when a member is positioned on another member “surface” or “above”, this includes not only when the member is in contact with the other member, but also when another member is present between the two members.

In the specification, the term “first and/or second” will be used to distinguish between components, and the components are not limited to the above-described terminology.

The singular forms are intended to include the plural forms unless the context clearly indicates otherwise.

Reference numerals in steps are only for the illustrative purpose, and not used to describe the sequence of the steps. The steps may be replicated in a sequence different from a sequence, which is described, unless otherwise specified.

Hereinafter, operational principles and embodiments of the present disclosure will be described with reference to the accompanying drawings.

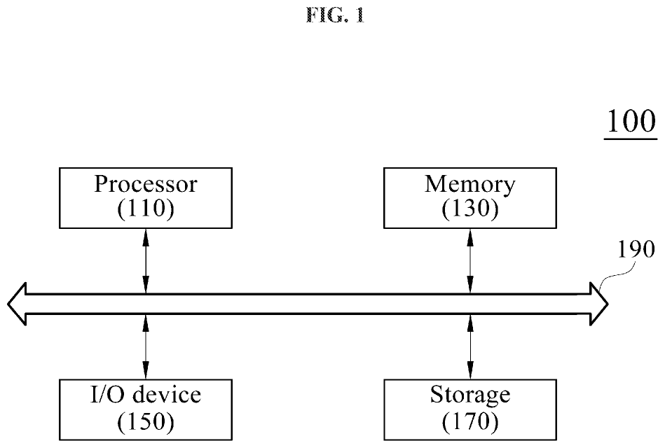

FIG. 1 illustrates a block diagram illustrating a semiconductor design system 100 according to an embodiment of the present disclosure. The semiconductor design system 100 serving as a computer system may perform a design method according to embodiments of the present disclosure, and may include a processor 110, a memory 130, an input/output device 150, a storage device 170, and a bus 190. In this case, the semiconductor design system 100 may load a program for placing a plurality of semiconductor devices in a designing region, according to the present disclosure and calculating a routing path between the plurality of semiconductor devices. In addition, the semiconductor design system 100 may be a computer system for driving various simulation tools or design tools.

The processor 110 is loaded into the memory 130 and executes software (an application program, an operating system, and a device driver) to be performed in the semiconductor design system 100. The operating system (OS) or application programs may be loaded into the memory 130. When the semiconductor design system 100 is booted, an OS image (not illustrated) stored in the storage device 170 may be loaded into the working memory 130 in a booting sequence. All input/output operations of the semiconductor design system 100 may be supported by the operating system (OS).

The input/output device 150 controls a user input and an output from a user interface device. For example, the input/output device 150 includes an input device, such as a keyboard, a mouse, and a touch pad, and an output device such as a monitor to receive information on a design rule.

The storage device 170 serves as a storage medium of the semiconductor design system 100. The storage device 170 may store the application programs, the operating system image (OS image), and various data.

In addition, the processor 110, the memory 130, the input/output device 150, and the storage device 170 may be electrically connected to each other and may exchange data with each other through the bus 190. However, the configuration of the system bus 190 is not limited to the above description.

A first algorithm (Smart Elbow) and a second algorithm (Generative Elbow) may be used in the design method according to an embodiment of the present disclosure. The first algorithm and the second algorithm, which are algorithms for generating an avoidance path for an avoidance target, may be used to calculate a routing path between a plurality of semiconductor devices, and the second algorithm will be described first for convenience of explanation. According to the design manner of an embodiment of the present disclosure, the following description will be made regarding that the first algorithm and the second algorithm are applied to the semiconductor design.

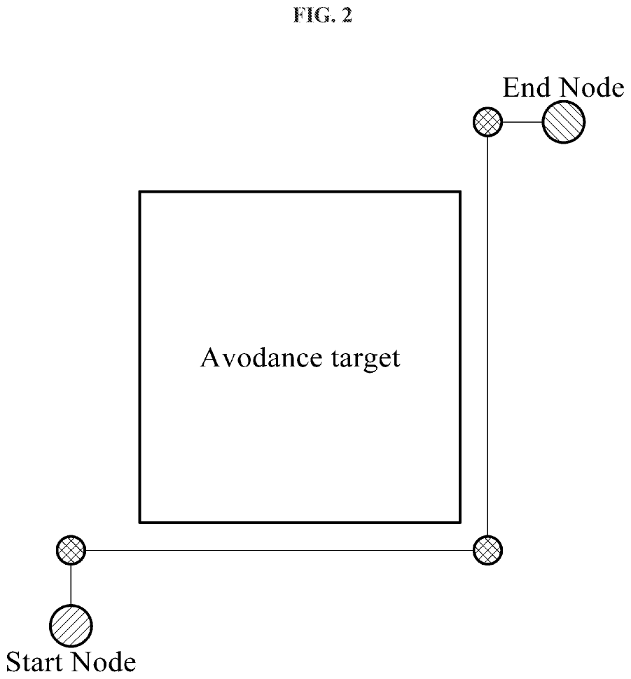

FIG. 2 is a view illustrating modifying a moving path to avoid an avoidance target by generating an additional node through the second algorithm.

According to an embodiment of the present disclosure, a node includes a start node, an end node, and at least one additional node added to create an avoidance path between the start node and the end node.

The processor 110 may generate a path (avoidance path) which may be moved by avoiding the avoidance target in the process of generating a routing path by adding at least one additional node around the avoidance target.

The processor 110 may modify the routing path to avoid the avoidance target in the process of generating the routing path by setting or adding at least one additional node around the avoidance target.

Coordinate values of the start node and the end node may be input as basic input values. In addition, information on the avoidance target may be input as a basic input value. As another variable, a right-angle auxiliary weight and an avoidance weight may be input.

According to an embodiment of the present disclosure, the processor 110 may determine or adjust the position of the additional node such that the routing path between the additional nodes has at a right angle (90°) according to the second algorithm. In addition, according to an embodiment of the present disclosure, the avoidance path, which shows a path change at a right angle from the additional node, may be expressed as ‘Elbow’.

According to an embodiment of the present disclosure, the routing path generated by the processor 110 by generating the avoidance path may be generated to include a right-angle elbow, and the path of the end node from the start node to another addition node, from the addition node to another addition node or another addition node may move at a right angle to avoid the avoidance target.

According to an embodiment, the processor 110 may calculate the sum tm(n) of vectors for maintaining avoidance and a right angle between adjacent nodes based on Equation 1.

$$tm ( n ) = ( {n}_{s} - pm ( {n}_{e} , {via ( n )}_{i} ) * {weight}_{d} + cpb ( n ) * {weight}_{c} \qquad \underline{Equation 1}$$

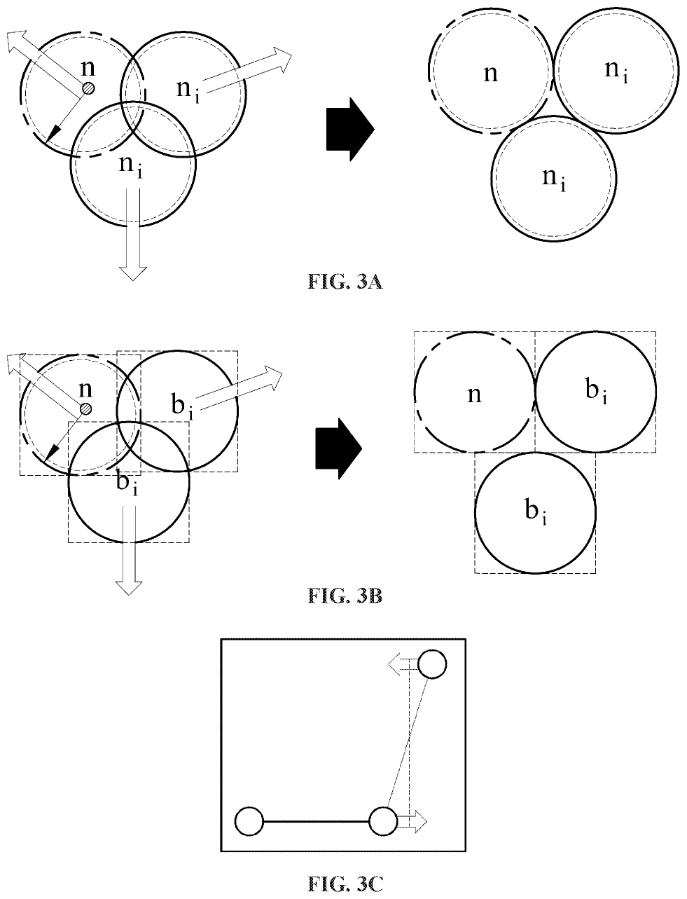

In this case, ‘tm’ refers ‘Total Move’, ‘via’ refers to a passage which is bored to transmit a signal between several layers constituting a semiconductor, and ‘via(n)’ refers to determining a semiconductor device which may pass through each layer. In addition, ‘pm(nₑ, via(n)i)’ refers to ‘nₑ’ in which node movement is performed through a right-angle correcting algorithm as illustrated in FIG. 3C, and refers to considering via when the right-angle correcting algorithm is applied.

In addition, ‘cpb(n)’ refers to Closest Points Between Line And Boxes, and as illustrated in FIG. 3B. According to the ‘Closest Points Between Line And Boxes’, as illustrated in FIG. 3B, boxes for all node collision regions are found, and pushed, when the boxes are overlapped with each other, which adjusting each node.

In other words, ‘tm’ is the sum of ‘pm(nₑ, via(n)i)×weight_{d}+cpb(n)×weight_{c}’.

In this case, ‘n’ refers to one of all nodes constituting the routing path, and refers to one straight path whose path which is not changed in the routing path.

In addition, ‘nₛ’ refers to vector coordinates of the start node, ‘nₑ’ refers to the vector coordinates of the node calculated through the algorithm, and ‘weight’ refers to the weight value. For example, ‘weight’ may be applied with an integer value such as ‘5’.

In other words, ‘tm(n)’ refers to a sum of values obtained by applying weights to paths by all calculated nodes.

According to an embodiment, the processor 110 may calculate a sum ‘tw(n)’ of weights for each node based on Equation 2.

$$tw ( n ) = {weight}_{d} + {weight}_{c} \qquad \underline{Equation 2}$$

In Equation 2, ‘tw(n)’ denotes total weights, and is an accumulated value by adding weights. According to an embodiment of the present disclosure, a value of 1 or more may be used as the weight, and ‘weight_{d}’ and ‘weight_{c}’ may be used, but the present disclosure is not limited thereto.

According to an embodiment, the processor 110 may calculate the final position ‘p(n)’ of the node based on Equation 3.

$$p ( n ) = n + tm ( n ) / tw ( n ) \qquad \underline{Equation 3}$$

In Equation 3, ‘p(n)’ refers to the final result of ‘n’, and ‘n’ refers to the value of the position vector of the node. In other words, ‘p(n)’ is a result of a movement coordinate value calculated for one node, and refers to a value obtained by adding the position coordinates of the input node to a value obtained by dividing the result value from Equations 1 by the result value from Equation 2.

As described above, the results values from Equations 1, 2, and 3 are calculated in real time by the processor 110, and the calculated result values from Equations 1 and 2 affect the result value from Equation 3 at the same time point and affect Equation 3 in the future.

According to the second algorithm, the avoidance target may be transformed and recognized in a preset shape (for example, a cylinder, or a sphere). For example, the avoidance target may be recognized as a cylinder-type box, but the present disclosure is not limited thereto.

According to the second algorithm, the avoidance path may be generated in a manner of excluding the avoidance target based on the node. In addition, according to the second algorithm, an interference may be avoided in a manner of excluding a reference obstacle based on the node. In addition, according to the second algorithm, the avoidance target may be gradually avoided and the routing path may be maintained to be at a right angle.

According to the second algorithm, the path may be edited and then recalculated. In addition, according to the second algorithm, the routing path may be maintained to be at the right angle gradually.

Through the above configurations, the second algorithm is based on the Circle Relation algorithm. Accordingly, all avoidance targets are transformed into preset figures and excluded from each other, thereby generating the avoidance path.

In addition, the second algorithm allows a rapid calculation speed due to the gradual calculation. According to the second algorithm, the calculation procedure may be provided for a user in real time, feedback and edited.

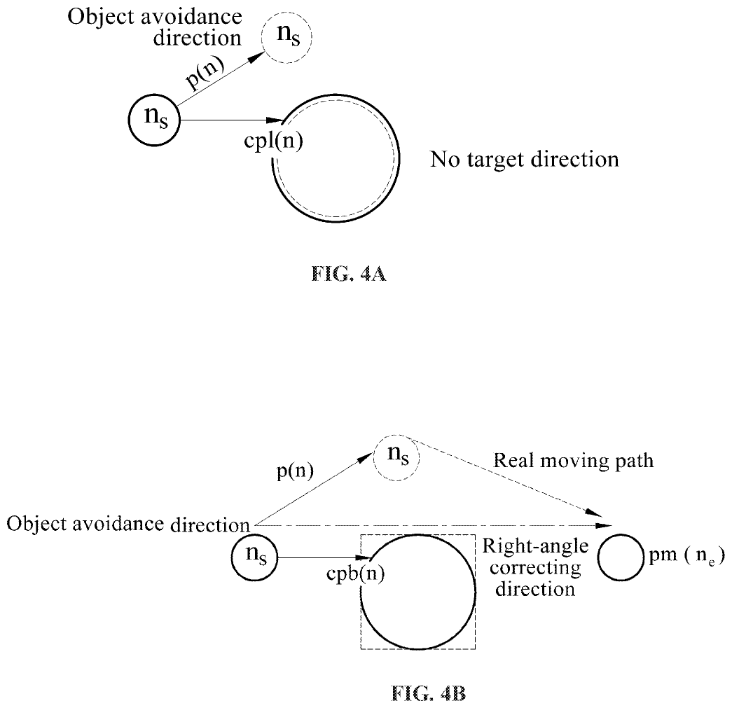

FIGS. 3A, 3B, and 3C and FIGS. 4A and 4B are views illustrating the features of a second algorithm.

Referring to FIG. 3A, an existing algorithm is to find a circle about the central point of each node and to push nodes when the circles are overlapped with each other. The scheme of the existing algorithm is appropriate to a cylindrical object. However, when the object is in another shape except form a cylinder, the node may be unnecessarily pushed.

To the contrast, referring to FIG. 3B, the second algorithm, which employs a scheme of finding boxes for all node collision regions, and pushing the boxes, when the boxes are overlapped with each other, is useful even when the object has a shape except for a cylinder.

In addition, referring to FIG. 3C, the processor 110 may correct or generate an avoidance path by moving the node such that the path between the nodes forms a right angle by using a right-angle correcting algorithm based on the second algorithm.

Referring to FIGS. 3B and 3C, the processor 110 may generate an avoidance path for the avoidance target using the following second algorithm.

The processor 110 may set at least one additional node for generating an avoidance path based on information on the avoidance target, set a virtual box having a preset size for each set additional node, move the position of the additional node to push overlapped regions, when the overlapped regions, in which virtual boxes set for the additional nodes are overlapped with each other, are present, maintain the boxes not to be overlapped with each other, when the overlapped regions are disappeared, as the positions of the additional nodes are moved, and create a final avoidance path by adjusting the position of the additional node such that the paths between the adjacent additional nodes form a right angle.

Referring to FIG. 4A, the existing algorithm is used when a target direction is not present. In other words, it refers to that there any end node is absent, according to an embodiment of the present disclosure. Therefore, according to an existing algorithm, the object avoidance value is reflected without the limitation for a forward direction.

FIG. 4B illustrates the application of the second algorithm, and according to the second algorithm, the path between nodes may form a right angle through the right-angle correcting algorithm of maintaining the avoidance state for the object (the avoidance target) and of correcting the positions of the nodes.

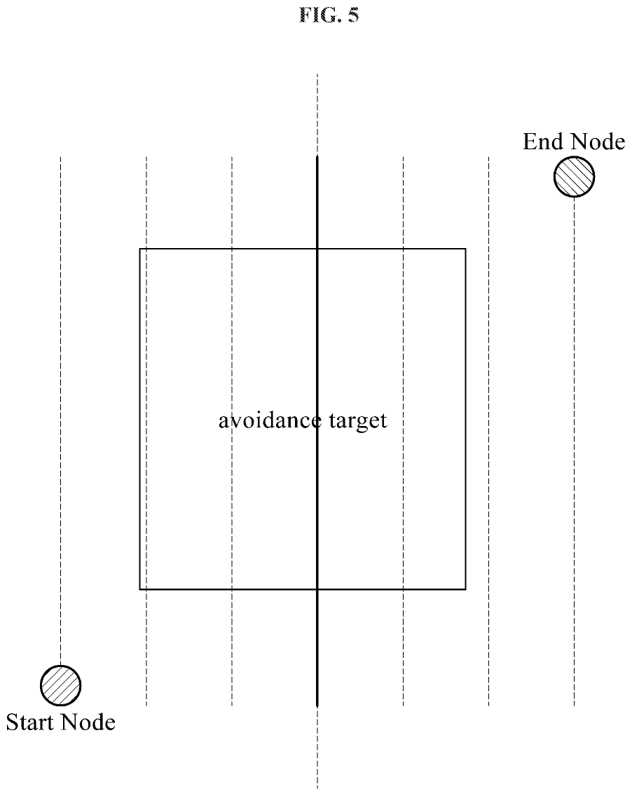

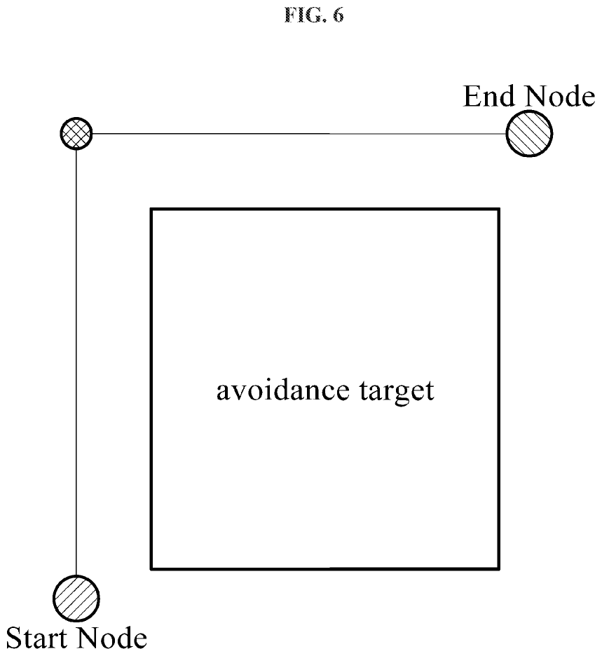

FIGS. 5 and 6 are views illustrating modifying a routing path to avoid the avoidance target by generating a node through the first algorithm.

Referring to FIGS. 5 and 6, the processor 110 may generate at least one line with respect to at least one axis of an x axis, a y axis, and a z axis from a start node to an end node, and may divided a region ranging from the start node to the end node into a plurality of regions, based on the generated line.

In this case, the processor 110 may divide the region into three to seven regions to prevent a computation amount from being excessively increased, such that processing is rapidly and efficiently performed. In addition, the line may be formed to include the start node or the end node. In this case, the processor 110 may delete a line, which is overlapped with the avoidance target, from among lines, and may design the avoidance path using the remaining line deleted.

The processor 110 may select the largest value from among results from heuristic functions for obtaining an expected minimum distance from a present node to a destination node through Equation 4.

According to an embodiment, the processor 110 may calculate the expected minimum distance between nodes using the heuristic function and select the largest value from the calculated expected minimum distance. The processor 110 may calculate a cost between nodes through Equation 5, and may calculate a total cost for each of a plurality of different path graphs by summing the result values from Equations 4 and 5.

$$h ( n ) = max \{ {h}_{1} ( n ) , {h}_{2} ( n ) , … , {h}_{i} ( n ) \} \qquad \underline{Equation 4}$$

$$g ( n ) = \sum [ w ( start , i ) + cost ( start , i ) ] \qquad \underline{Equation 5}$$

In Equation 4, ‘h(n)’ may be calculated by selecting the largest value among heuristic functions for obtaining an expected minimum distance from the present node to the destination node. In Equation 4, h1(n), h2(n), . . . and hi(n) refer to calculate a heuristic function for all paths from the start node to the end node.

In Equation 5, ‘g(n)’ refers to the cost (cost) from the start node to the present node.

In Equation 5, ‘w(start, i)’ refers to a weight value required for movement from the start node to the present node, and ‘cost(start, i)’ refers to a real distance value from the start node to the present node.

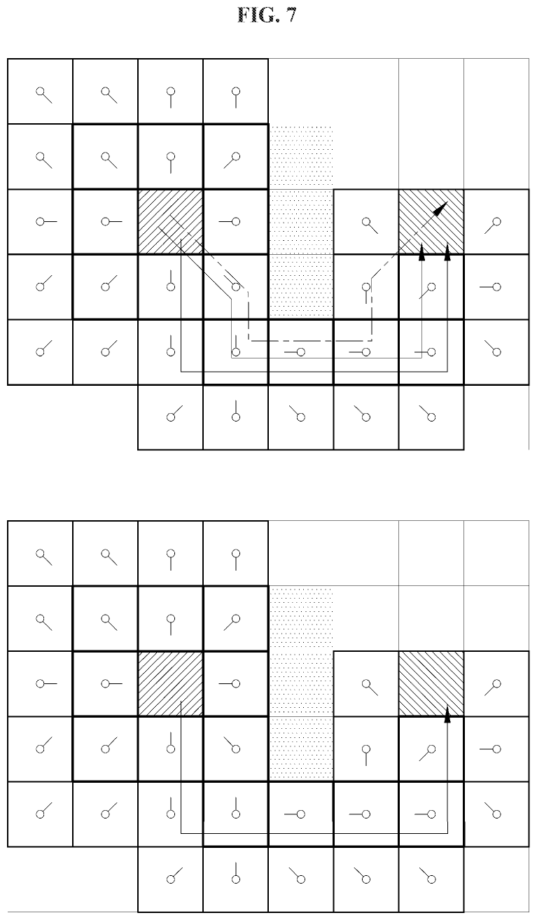

FIG. 7 is a view illustrating features of a first algorithm.

Referring to FIG. 7, according to an embodiment, the processor 110 may control to generate a path graph only at a right angle in an A* algorithm, and may set a weight to prefer an existing forwarding path (travelling path) when generating a path, thereby adding nodes in minimum number.

The processor 110 may generate a final moving path by calculating the shortest distance within results satisfying the above conditions.

According to the first algorithm, coordinate values of the start node and the end node may be input as basic input values. In addition, information on the avoidance target may be input as the basic input value. Another variable may include ‘penalty weight’, ‘x-axis region division count(int)’, ‘y-axis region division count(int)’, and ‘z-axis region division count(int)’.

According to an embodiment, the processor 110 may calculate ‘h(n)’, ‘g(n)’, and ‘f(n)’ respectively as in Equations 6, 7, and 8 below by applying ‘penalty weight’ for the first algorithm.

$$h ( n ) = max \{ {h}_{1} ( n , pw , {via ( n )}_{i} ) , {h}_{2} ( n , pw , {via ( n )}_{i} ) , … , {h}_{i} ( n , pw , {via ( n )}_{i} ) \} \qquad \underline{Equation 6}$$

In Equation 6, the heuristic functions are calculated for all paths from a start node to an end node. Unlike a general heuristic function, a right angle is formed by inputting a value of pw (penalty weight), in which the penalty weight is in, for example, ‘0’ to ‘5’. In this case, the path is a path passing through a via.

According to some embodiments, when the path is not found horizontally or vertically, the processor 110 may modify the value of ‘pw’ to allow a diagonal path.

$$g ( n ) = \sum [ w ( start , i ) + cost ( start , i ) ] \qquad \underline{Equation 7}$$

In Equation 7, ‘g(n)’ refers to a cost (cost) required from the start node to the present node, ‘w(start, i)’ refers to a weight value required for movement from the start node to the present node, and cost(start, i) refers to an actual distance value from the start node to the present node.

$$f ( n ) = g ( n ) + h ( n , pw , {via}_{i} ) \qquad \underline{Equation 8}$$

In Equation 8, ‘h(n, pw, via)’ may be calculated by selecting the largest value from among the heuristic functions for obtaining the expected minimum distance through the via from the present node to the destination node.

According to an embodiment of the present disclosure, Equations 4 and 5 may apply the A* algorithm, and allow diagonal movement. In contrast, Equations 6, 7, and 8 are algorithms that complement the A* algorithm, and are equations obtained by adding ‘pw (penalty weight)’, which serves as an input value of a heuristic function, to Equations 4 and 5. Equations 6, 7, and 8 have effects of generating the path only at the right angle by inputting ‘pw’ when calculating the heuristic function.

However, according to some embodiments, the processor 110 may allow a diagonal path by modifying the value of ‘pw’ when the path is not found horizontally or vertically.

The first algorithm may recognize the avoidance target in the shape of the avoidance target, generate a path graph for all possible paths from the start node to the end node, delete the path graph overlapped with the avoidance target from among the path graphs for all paths, and select the final avoidance path from the remaining path graphs.

In addition, the first algorithm may generate the path graph such that all paths included in the path graph form only a right angle.

The first algorithm is based on the A* algorithm, calculates all possible paths from the start node to the end node, and selects the most reasonable path from among the all possible paths from the start node to the end node.

The first algorithm has the advantage of being able to absolutely avoid a target to be avoided and maintaining a right-angled path between nodes.

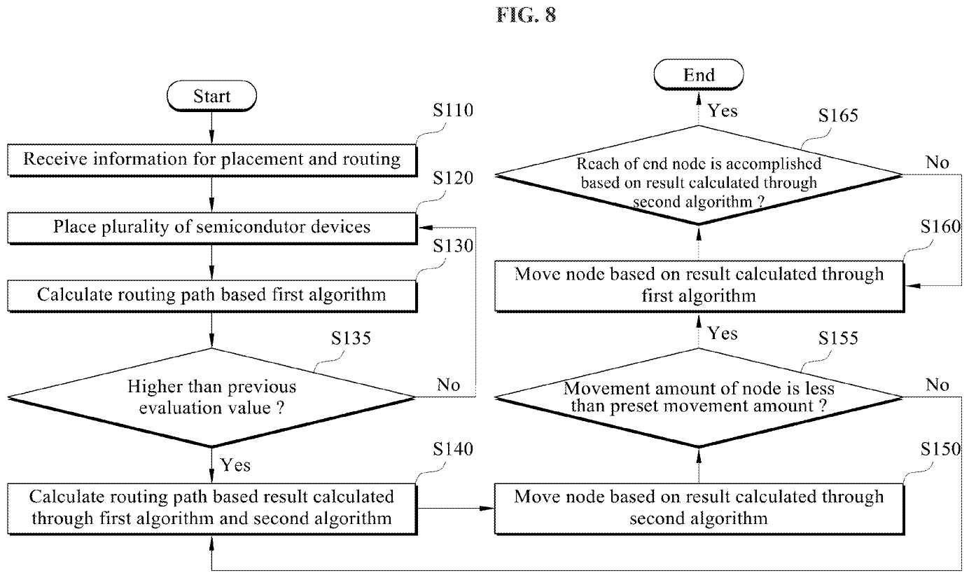

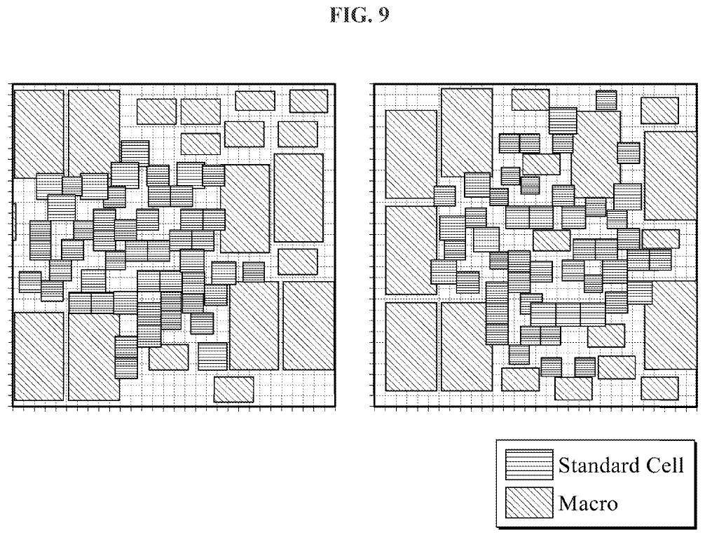

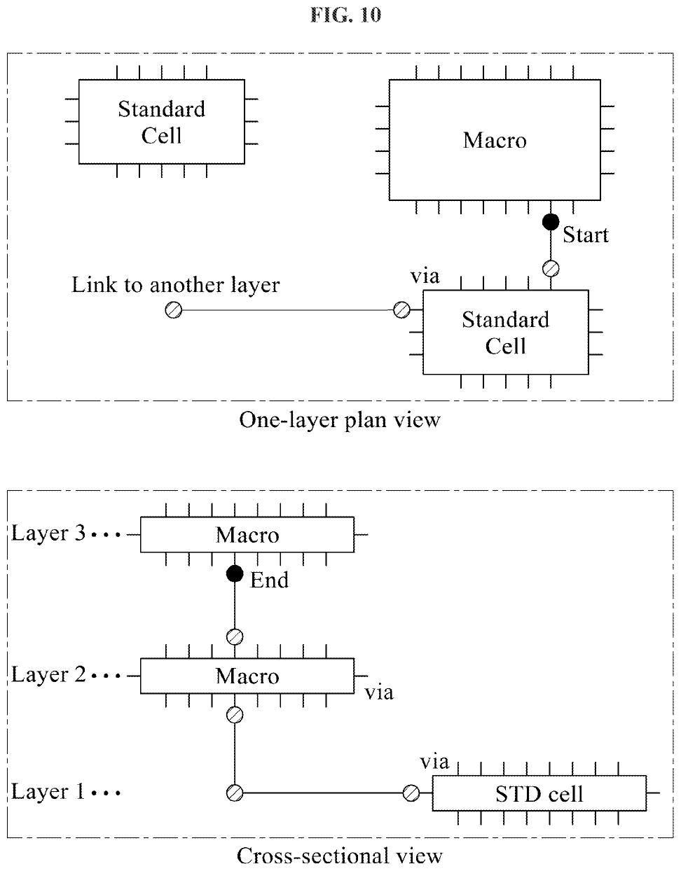

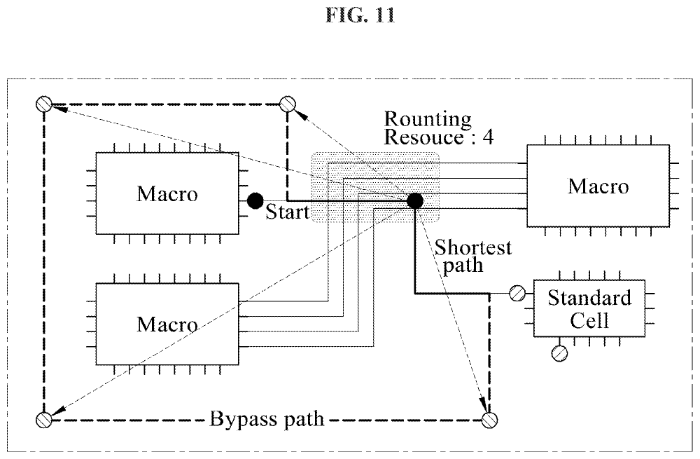

Hereinafter, a design method for placing and routing a semiconductor in a computer system according to an embodiment of the present disclosure will be described with reference to FIGS. 8 to 11. FIG. 8 is a flowchart illustrating the design method, according to an embodiment of the present disclosure, FIG. 9 is a view illustrating the placement of a plurality of semiconductor devices, FIG. 10 is a view illustrating the shortest distance of a routing path through a via, and FIG. 11 is a view illustrating the generation of a bypass path according to a second algorithm.

First, the processor 110 receives information for placement and routing of a plurality of semiconductor devices (S110).

The processor 110 may receive a design rule for each manufacturer (circuit line width, circuit line spacing, and interlayer spacing), and may receive various variables suitable for the first and second algorithms.

For example, the processor 110 may receive values such as a start node/end node, the list of an avoidance region, an elbow maximum/minimum value, a move weight, a penalty weight, an x-axis region division count (int), a y-axis region division count (int), and a z-axis region division count (int).

Meanwhile, in the design method for placing and routing the semiconductor devices according to one embodiment of the present disclosure, a design may be made in that a semiconductor or semiconductor chip may form multiple layers, and a via may be formed between multiple layers to transmit a signal.

Subsequently, the processor 110 places a plurality of semiconductor devices in the design region (S120).

The plurality of semiconductor devices includes a plurality of macros and a plurality of standard cells. In this case, the plurality of macros may include a CPU, or a RAM, but the present disclosure is not limited thereto.

A deadspace, which is an empty space between a macro and a macro, needs to be minimized because an adverse effect may be made on a routing process when the deadspace is formed and a standard cell is interposed within the deadspaces. In addition, a signal may be distorted when wires may be overlapped with each other in the routing path, so the placement of the macro and the standard cell needs to be optimized to prevent the wires from being overlapped with each other.

Therefore, referring to FIG. 9, the processor 110 may minimize the deadspace by placing multiple macros along the edge of the designing region and then placing the multiple standard cells.

In addition, the processor 110 may place semiconductor devices having a higher connection frequency to be closer to each other, and randomly place the remaining semiconductor devices.

This placement is performed before determining the via, and the processor 110 may determine the via after placing the plurality of semiconductor devices in the designing region.

Subsequently, the processor 110 calculates (see S130) and evaluates (see S135) a routing path between the plurality of semiconductor devices based on the first algorithm (Smart Elbow).

First, regarding that the processor 110 calculates the routing path between the plurality of semiconductor devices through the first algorithm, the first algorithm is to recognize the shape of the avoidance target itself in the process of calculating the routing path, and delete a path graph, which is overlapped with the avoidance target, among path graphs for all possible routing paths from the start node to the end node, after generating the path graph for the all possible routing paths from the start node to the end node.

Specifically, referring to FIG. 10, according to the first algorithm, when the design region has a plurality of layers, the processor 110 finds the shortest path passing through a via. The processor 110 may generate a path in the horizontal direction and the vertical direction through a via. However, when a path in the horizontal direction and the vertical direction is not found, a diagonal path may be generated by modifying the value of ‘pw’. However, when wires are arranged in the horizontal direction, since there are many cases of excellent performance due to low propagation delay and low interference or distortion noise, generation of a routing path in the diagonal direction may be used to a minimum, when the routing path may not be generated in the horizontal and vertical directions.

In addition, according to the first algorithm, the processor 110 should avoid wires or a via, when the wires are overlapped with each other or the via is not target for passing. In addition, wires in number larger than the number of routing resources may not be disposed.

This series of processes may be performed through Equation 8.

The processor 110 evaluates the result calculated in step S130, and the evaluation score may be determined depending on the length (wire length) of the wire resulting from the routing path and the number of elbows. Specifically, as the length of the wire resulting from the routing path is decreased, the evaluation score is increased. As the number of elbows is decreased, the evaluation score is increased.

Through such design and evaluation, the processor 110 may minimize and optimize the wire length based on the design rule. When optimizing the wire length, a circuit line width, a circuit line margin, interlayer spacing, and routing resources may be considered.

The processor 110 performs the step S140 to calculate and compare the routing path based on the second algorithm, when a present evaluation score is higher than a previous evaluation score depending on the evaluation result. The processor 110 iterates the step S120 of placing a plurality of semiconductor devices, the step (S130) of calculating the routing path based on the first algorithm, and the step (S135) of evaluating the routing path based on the first algorithm, when the present evaluation score is not higher than the previous evaluation score depending on the evaluation result.

Subsequently, according to the evaluation result, the processor 110 calculates a routing path between the plurality of semiconductor devices based on the result calculated through the first algorithm (Smart Elbow) and the second algorithm (Generative Elbow) (S140).

First, regarding that the processor 110 calculates the routing path between the plurality of semiconductor devices based on the second algorithm, the second algorithm is to recognize a shape of an avoidance target as a shape of a cylinder-type box in calculating the routing path, move a position of a node, such that regions, which are overlapped with each other, of boxes are pushed, when regions, which are overlapped with each other, of boxes are present, and maintain the boxes, such that the regions, which are overlapped with each other, of the boxes are absent, when the regions are disappeared, as the position of the node moves, and calculate the routing path in a manner of adjusting the position of the node such that a path between adjacent nodes forms a right angle.

Specifically, the processor 110 calculates a routing path between a plurality of semiconductor devices based on a result calculated through the first algorithm and the second algorithm. In this case, the processor 110 calculates the routing path between the plurality of semiconductor devices, based on the number of elbows obtained from the result calculated through the first algorithm and the second algorithm.

In other words, in the state that the number of elbows is fixed to the number of elbows obtained from the result calculated through the first algorithm, the processor 110 calculates the routing path between the plurality of semiconductor devices based on the second algorithm.

In addition, according to the second algorithm, when the wires are overlapped with each other or the via needs not to pass in the process of generating the routing path, the processor 110 has to avoid the wires and the via, and the wires in number larger than the number of routing resources may not be placed. Besides, referring to FIG. 11, the processor 110 gradually moves the elbows by adjusting the elbows while generating a bypass path.

Meanwhile, according to the second algorithm, the processor 110 may move a node through a right-angle correcting algorithm in the process of generating the routing path. In addition, the processor 110 may make a design based on a design rule, such that the wire length is decreased, and the number of elbows is decreased, while minimizing and optimizing the wire length.

Subsequently, the processor 110 compares the result calculated through the first algorithm with the result calculated through the second algorithm (S150 and S155).

Specifically, comparing, by the processor 110, the result calculated through the first algorithm with the result calculated through the second algorithm includes moving a node based on the result calculated through the first algorithm to a node based on the result calculated through the second algorithm (step S150), and determining whether a movement amount of the nodes in the moving operation is less than a preset movement amount (S155).

In other words, according to the design method according to the present disclosure, whether the difference in movement amount between the node based on the result calculated through the first algorithm and the node based on the result calculated through the second algorithm is equal to or less than the preset movement amount is determined to verify the result calculated through the first algorithm using the result calculated through the second algorithm.

Therefore, according to the design method of the present disclosure, the optimization of the routing path may be reliable.

In this case, when the movement amount of the node is less than the preset movement amount according to the comparison result, the processor 110 proceeds to the step of verifying the result calculated through the first algorithm (S160 and S165). When the movement amount of the node is not less than the preset movement amount according to the comparison result, the processor 110 may iterate the step of calculating the routing path between the plurality of semiconductor devices, based on the result calculated through the first algorithm and the second algorithm (S140, S150, and S155).

Subsequently, the processor 110 verifies the result calculated through the first algorithm according to the comparison result (S160 and S165).

In this case, the verifying by the processor 110 of the result calculated through the first algorithm includes determining whether a node reaches an end node based on the result calculated through the second algorithm even if the result calculated through the first algorithm is satisfied. Specifically, the processor 110 moves the node based on the result calculated through the second algorithm to the node based on the result calculated through the first algorithm (S160), and determines whether a node reaches an end node based on the result calculated through the second algorithm even if the result calculated through the first algorithm is satisfied (S165).

When it is not determined that a node reaches an end node based on the result calculated through the second algorithm even if the result calculated through the first algorithm is satisfied, the processor 110 may additionally perform the optimization based on the first algorithm, through the step (S150) of moving the node based on the result calculated through the second algorithm to the node based on the result calculated through the first algorithm.

Accordingly, in the design method according to the present disclosure, the optimized routing path may be designed.

As described above, the method according to an embodiment of the present disclosure may be implemented in the form of a program (or application) to be stored in a medium, so as to be executed in combination with a computer which is hardware.

Embodiments of the present disclosure may be implemented in the form of a recording medium to store an instruction executable by the computer. The instruction may be stored in the form of a program code. When the instruction is executed by a processor, the operation of embodiments of the present disclosure may be performed by creating a program module. The recording medium may be implemented in the form of the recording medium readable by a computer.

The recording medium readable by the computer includes all type of recording media having an instruction decrypted by the computer. For example, the recording medium may include a read only memory, a random access memory (RAM), a magnetic tape, a magnetic disc, a flash memory, and an optical data storage device.

As described above, according to the present disclosure, the optimal vias may be formed in a multiple-layered semiconductor. Accordingly, the present disclosure is applicable to a technology related to through silicon via (TSV). Accordingly, the present disclosure may be used in the process of packaging an artificial intelligence (AI) semiconductor, such as a high bandwidth memory (HBM), a central processing unit (CPU), or a graphic processing unit (GPU).

As described above, according to the present disclosure, the placement and the routing path of the semiconductor device may be optimally designed based on the design rule.

As described above, according to the present disclosure, the micro-cell and the standard cell may be placed to reduce the deadspace and the routing path may be designed to minimize the wire length, by utilizing plurality of algorithms.

The effects of the present disclosure are not limited to the effects mentioned above, and other effects not mentioned will be clearly understood by those skilled in the art from the following description.

As describe above the embodiments of the present disclosure have been described with reference to accompanying drawings. Although embodiments of the present disclosure have been described with reference to the accompanying drawings, it will be understood by those skilled in the art to which the present disclosure pertains that the present disclosure may be carried out in other detailed forms without changing the technical spirits and essential features thereof. The embodiments of the present disclosure are provided only for the illustrative purpose, and the present disclosure should not be interpreted to be limited.

While the present disclosure has been described with reference to embodiments, it will be apparent to those skilled in the art that various changes and modifications may be made without departing from the spirit and scope of the present disclosure. Therefore, it should be understood that the above embodiments are not limiting, but illustrative.

What is claimed is:

1. A design method for placing and routing a semiconductor device in a computer system, the design method comprising:
placing, by the computer system, a plurality of semiconductor devices in a design region;
calculating and evaluating, by the computer system, a routing path between the plurality of semiconductor devices, based on a first algorithm;
calculating, by the computer system, the routing path between the plurality of semiconductor devices based on a result calculated through the first algorithm and a second algorithm, based on an evaluation result, and comparing the result calculated through the first algorithm with a result calculated through the second algorithm; and
verifying the result calculated through the first algorithm, based on a comparison result.

2. The design method of claim 1, wherein the placing of by the computer system, the plurality of semiconductor devices in the design region includes;
placing, by the computer system, semiconductor devices, which have a higher connection frequency, from among the plurality of semiconductor devices to be closer to each other, and randomly placing remaining semiconductor devices from among the plurality of semiconductor devices.

3. The design method of claim 1, wherein, in the placing of by the computer system, the plurality of semiconductor devices in the design region,
the plurality of semiconductor devices include a plurality of macros and a plurality of standard cells, and
the computer system places the plurality of standard cells, after placing the plurality of macros, along an edge of the design region.

4. The design method of claim 1, wherein the first algorithm is to:
recognize a shape of an avoidance target in calculating the routing path; and
delete a path graph, which is overlapped with the avoidance target, among path graphs for all possible routing paths from a start node to an end node, after generating the path graph for the all possible routing paths from the start node to the end node, and
wherein the second algorithm is to:
recognize a shape of an avoidance target as a shape of a cylinder-type box in calculating the routing path;
move a position of a node, such that regions, which are overlapped with each other, of boxes are pushed, when regions, which are overlapped with each other, of boxes are present; and
maintain the boxes, such that the regions, which are overlapped with each other, of the boxes are absent, when the regions are disappeared, as the position of the node moves, and calculate the routing path in a manner of adjusting the position of the node such that a path between adjacent nodes forms a right angle.

5. The design method of claim 4, wherein the first algorithm is to generate the routing path in a horizontal direction, a vertical direction through a via, and a diagonal direction, when the design region includes a plurality of layers.

6. The design method of claim 1, wherein the computer system:
calculates and compare the routing path based on the second algorithm, when a present evaluation score is higher than a previous evaluation score, depending on the evaluation result, and
places the plurality of semiconductor devices, calculates the routing path based on the first algorithm, and evaluates the routing path based on the first algorithm, when the present evaluation score is not higher than the previous evaluation score, depending on the evaluation result, depending on the evaluation result.

7. The design method of claim 6, wherein an evaluation score is determined depending on a wire length resulting from the routing path and the number of elbows.

8. The design method of claim 1, wherein the computer system:
calculates the routing path between the plurality of semiconductor devices, based on the result calculated through the first algorithm and the second algorithm; and
calculates the routing path between the plurality of semiconductor devices, based on the number of elbows obtained from the result calculated through the first algorithm and the second algorithm.

9. The design method of claim 1, wherein the comparing of by the computer system, the result calculated through the first algorithm with the result calculated through the second algorithm includes:
determining whether a movement amount when a node based on the result calculated through the first algorithm is moved to a node based on the result calculated through the second algorithm is less than a preset movement amount.

10. The design method of claim 9, wherein the computer system:
verifies the calculation result based on the first algorithm, when the movement amount of the nodes is less than the preset movement amount, depending on the comparison result, and
calculates the routing path between the plurality of semiconductor devices, based on the result calculated through the first algorithm and the second algorithm, when the movement amount of the nodes is not less than the preset movement amount, depending on the comparison result.

11. The design method of claim 1, wherein the verifying of by the computer system, the result calculated through the first algorithm includes:
determining whether a node reaches an end node based on the result calculated through the second algorithm even if the result calculated through the first algorithm is satisfied.

12. A computer-readable recording medium having program to execute design method of claim 1, in link to a computer implemented in hardware.
